(19) United States
(12) Patent Application Publication
(10) Pub. No.: US 2006/0225273 A1
(43) Pub. Date: Oct. 12, 2006

(54) Transferring die(s) from an intermediate surface to a substrate

(75) Inventors: Michael R. Arneson, Finksburg, MD (US); William R. Bandy, Gambrills, MD (US)

Correspondence Address: STERNE, KESSLER, GOLDSTEIN & FOX PLLC, 1100 NEW YORK AVENUE, N.W., WASHINGTON, DC, 20005, US

(73) Assignee: Symbol Technologies, Inc., Holtsville, NY (US)

(21) Appl. No.: 11/091,944

(22) Filed: Mar. 29, 2005

(51) Int. Cl. H05K 3/30; B23P 19/00

(52) U.S. Cl. 29/834; 29/740

(57) ABSTRACT

Dies that are attached to a die plate can be transferred to a substrate. For example, holes in the die plate can be filled with an expandable material. A stimulus source, such as a laser beam/laser light can be directed to the material in a hole, causing the material to expand. Expansion of the material can cause a die that is covering the hole to be released from the die plate to come into contact with a substrate. A mask can be used to prevent the material in a hole from being expanded by the stimulus source. In another example, a pin plate is used to release a die from the die plate. Pins of the pin plate are selectively actuated to cause selected die(s) to be released. An actuator plate having a plurality of actuators can be moved across the pin plate, with actuator(s) selectively actuating corresponding pin(s).

### CROSS-REFERENCE TO RELATED APPLICATIONS

The following applications of common assignee are herein incorporated by reference in their entireties:

“Method and Apparatus for High Volume Assembly of Radio Frequency Identification Tags,” Ser. No. 10/322,467, filed Dec. 19, 2002 (Atty. Dkt. No. 1689.0110001);

“Method and System for Forming a Die Frame and for Transferring Dies Therewith,” Ser. No. 10/429,803, filed May 6, 2003 (Atty. Dkt. No. 1689.0110005);

“Method, System, and Apparatus for Transfer of Dies Using a Pin Plate,” Ser. No. 10/866,159, filed Jun. 14, 2004 (Atty. Dkt. No. 1689.0560000); and

“Method, System, And Apparatus For High Volume Transfer Of Dies,” Ser. No. 10/866,149, filed Jun. 14, 2004 (Atty. Dkt. No. 1689.0580000).

### BACKGROUND OF THE INVENTION

1. Field of the Invention

The present invention relates generally to the assembly of electronic devices. More particularly, the present invention relates to the transfer of integrated circuit (IC) dies to surfaces in high volumes.

2. Related Art

Pick and place techniques are often used to assemble electronic devices. Such techniques involve a manipulator, such as a robot arm, to remove integrated circuit (IC) chips or dies from a wafer and place them into a die carrier. The dies are subsequently mounted onto a substrate with other electronic components, such as antennas, capacitors, resistors, and inductors to form an electronic device.

Pick and place techniques involve complex robotic components and control systems that handle only one die at a time. This has a drawback of limiting throughput volume. Furthermore, pick and place techniques have limited placement accuracy, and have a minimum die size requirement.

One type of electronic device that may be assembled using pick and place techniques is an RFID “tag.” An RFID tag may be affixed to an item whose presence is to be detected and/or monitored. The presence of an RFID tag, and therefore the presence of the item to which the tag is affixed, may be checked and monitored by devices known as “readers.”

As market demand increases for products such as RFID tags, and as die sizes shrink, high assembly throughput rates and low production costs are crucial in creating commercially viable products. Accordingly, what is needed is a method and apparatus for high volume assembly of electronic devices, such as RFID tags, that overcomes these limitations.

### SUMMARY OF THE INVENTION

The present invention is directed to methods, systems, and apparatuses for producing one or more electronic devices, such as RFID tags, that each include one or more dies. The dies each have one or more electrically conductive contact pads that provide for electrical connections to related electronics on a substrate.

According to embodiments of the present invention, electronic devices are formed at greater rates than conventionally possible. In one aspect, large quantities of dies can be transferred directly from a wafer to corresponding substrates of a web of substrates. In another aspect, large quantities of dies can be transferred from a support surface to corresponding substrates of a web of substrates. In another aspect, large quantities of dies can be transferred from a wafer or support surface to an intermediate surface, such as a die plate. The die plate may have cells formed in a surface thereof in which the dies reside. Otherwise, the dies can reside on a surface of the die plate. The dies of the die plate can then be transferred to corresponding substrates of a web of substrates.

In an embodiment, a plurality of integrated circuit dies is transferred from a die plate to a substrate by expanding material in holes of a die plate. The die plate has a first surface having a plurality of dies attached thereto The dies each cover a corresponding hole through the die plate. A transparent body is positioned against a second surface of the die plate. The first surface of the die plate and the substrate are positioned to be adjacent to each other such that the dies are closely adjacent to corresponding contact areas on a first surface of the substrate. A stimulus is applied through the transparent planar body to a material filling the holes in the die plate to cause the dies to be released from the die plate to come into contact with the contact areas.

According to an embodiment, a laser heats the material through the transparent planar body to cause the material to expand, thereby causing die(s) to be released from the die plate.

In an embodiment, the stimulus is selectively applied through the transparent planar body. For example, a mask can cover other hole(s) in the die plate. In an alternative embodiment, the stimulus is applied to all dies that are attached to the first surface of the die plate to cause each of the dies to be released from the die plate to come into contact with a corresponding contact area on the substrate.

According to an embodiment, the die plate is received having the holes empty. The empty holes are filled with the material, and the dies are positioned onto the first surface of the die plate over the holes that are filled with the material. In an alternative embodiment, the dies are positioned onto the first surface of the die plate over the empty holes, which are then filled with the material.

The die plate can have any number of one or more dies attached to the first surface of the die plate, and the die plate can have a corresponding number of holes therethrough. For instance, each die of the plurality of dies can cover a corresponding hole through the die plate.

In an embodiment, a plurality of integrated circuit dies is transferred from a die plate to a substrate by selectively actuating pins of a pin plate. For example, a pin of a pin plate is aligned with a hole in the die plate. An actuator selectively actuates the pin to cause a corresponding die to be released from the die plate to come into contact with a corresponding contact area on the first surface of the substrate. The pin plate may include at least a portion of the actuator. Selectively actuating the pin can be performed by selectively energizing a coil associated with the pin, for example.

According to an embodiment, an actuator plate having a plurality of actuators is moved across the pin plate. One or more actuators selectively actuate corresponding pins of the pin plate. In an alternative embodiment, the pin plate is moved across the die plate. Pins of the pin plate are selectively actuated as the pin plate is moved across the die plate. For example, the pins can be selectively moved into holes of die plate a number of rows or columns at a time.

These and other advantages and features will become readily apparent in view of the following detailed description of the invention. Note that the Summary and Abstract sections may set forth one or more, but not all exemplary embodiments of the present invention as contemplated by the inventor(s), and thus, are not intended to limit claims.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a block diagram of an exemplary RFID tag, according to an embodiment of the present invention.

FIGS. 2A and 2B show plan and side views of an exemplary die, respectively.

FIGS. 2C and 2D show portions of a substrate with a die attached thereto, according to example embodiments of the present invention.

FIG. 3 is a flowchart illustrating a device assembly process, according to embodiments of the present invention.

FIGS. 4A and 4B are plan and side views of a wafer having multiple dies affixed to a support surface, respectively.

FIG. 5 is a view of a wafer having separated dies affixed to a support surface.

FIG. 6 shows a system diagram illustrating example options for transfer of dies from wafers to substrates, according to embodiments of the present invention.

FIG. 7 is a flowchart of a method for transferring dies from an intermediate surface to a substrate using a changeable or movable material, according to embodiments of the present invention.

FIG. 8 is a cross-sectional view of a die plate, according to an embodiment of the present invention.

FIG. 9 is a cross-sectional view of the die plate shown in FIG. 8 having filled holes, according to an embodiment of the present invention.

FIG. 10 is plan view of the die plate shown in FIG. 9, according to an embodiment of the present invention.

FIG. 11 is a system having a transparent planar body, according to an embodiment of the present invention.

FIG. 12 is a system having a stimulus source, according to an embodiment of the present invention.

FIG. 13 is a system having an expandable material in holes of a die plate, according to an embodiment of the present invention.

FIG. 14 is a flowchart of a method for selectively transferring dies from an intermediate surface to a substrate, according to embodiments of the present invention.

FIG. 15 shows an example pin plate, according to an embodiment of the present invention.

FIG. 16 shows a body of the pin plate shown in FIG. 15 having holes, according to an embodiment of the present invention.

FIG. 17 shows pins of the pin plate shown in FIG. 15 aligned with corresponding holes of a die plate, according to an embodiment of the present invention.

FIG. 18 shows a pin of the pin plate shown in FIG. 15 being selectively actuated, according to an embodiment of the present invention.

FIG. 19 shows a further pin of the pin plate shown in FIG. 15 being actuated, according to an embodiment of the present invention.

FIG. 20 shows example actuators coupled to respective pins of the pin plate shown in FIG. 15, according to an embodiment of the present invention.

FIG. 21 shows a pin of the pin plate shown in FIG. 15 selectively actuated, according to an example embodiment of the present invention.

FIG. 22 shows example actuators coupled to respective pins of the pin plate shown in FIG. 15, according to another embodiment of the present invention.

FIG. 23 shows a pin of the pin plate shown in FIG. 15 selectively actuated, according to another example embodiment of the present invention.

FIG. 24 shows a stimulus plate having stimulators, according to an example embodiment of the present invention.

FIG. 25 shows a perspective view of the stimulus plate shown in FIG. 24, according to an embodiment of the present invention.

FIG. 26 shows a pin plate having a single column of pins, according to an embodiment of the present invention.

FIG. 27 illustrates a pin plate in which pins are selectively actuated as the pin plate is moved across a die plate.

FIG. 28 shows a pin plate having two columns of pins, according to another embodiment of the present invention.

FIG. 29 illustrates a system in which pins of the pin plate as shown in FIG. 26 are selectively actuated as the pin plate moves across the die plate, according to an embodiment of the present invention.

FIG. 30 shows a system in which pins are included in holes of a die plate, according to an embodiment of the present invention.

The present invention will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE INVENTION

1.0 Overview

The present invention provides improved processes and systems for assembling electronic devices, including RFID tags. The present invention provides improvements over previous processes. Conventional techniques include vision-based systems that pick and place dies one at a time onto substrates. The present invention can transfer multiple dies simultaneously. Vision-based pick and place systems are limited as far as the size of dies that may be handled, such as being limited to dies larger than 600 microns square. The present invention is applicable to dies 100 microns square and even smaller. Furthermore, yield is poor in conventional systems, where two or more dies may be accidentally picked up at a time, causing losses of additional dies. The present invention allows for improved yield values.

The present invention provides an advantage of simplicity. Conventional die transfer tape mechanisms may be used by the present invention. Furthermore, much higher fabrication rates are possible. Previous techniques processed 5-8 thousand units per hour. The present invention provides improvements in these rates by a factor of N. For example, embodiments of the present invention can process dies 5 times as fast as conventional techniques, at 100 times as fast as conventional techniques, and at even faster rates. Furthermore, because the present invention allows for flip-chip die attachment techniques, wire bonds are not necessary. However, in embodiments, the present invention is also applicable to wire bonded die embodiments.

Elements of the embodiments described herein may be combined in any manner. Example RFID tags are described in section 1.1. Assembly embodiments for devices are described in section 1.2. More detailed assembly embodiments for devices are described in sections 2.0 and 3.0.

1.1 Example Electronic Device

The present invention is directed to techniques for producing electronic devices, such as RFID tags. For illustrative purposes, the description herein primarily relates to the production of RFID tags. However, the invention is also adaptable to the production of further electronic device types (e.g., electronic devices including one or more IC dies or other electrical components mounted thereto), as would be understood by persons skilled in the relevant art(s) from the teachings herein. Furthermore, for purposes of illustration, the description herein primarily describes attachment of dies to substrates. However, embodiments of the present invention are also applicable to the attachment of other types of electrical components to substrates, including any type of surface mount component (e.g., surface mount resistors, capacitors, inductors, diodes, etc.), as would be understood by persons skilled in the relevant art(s).

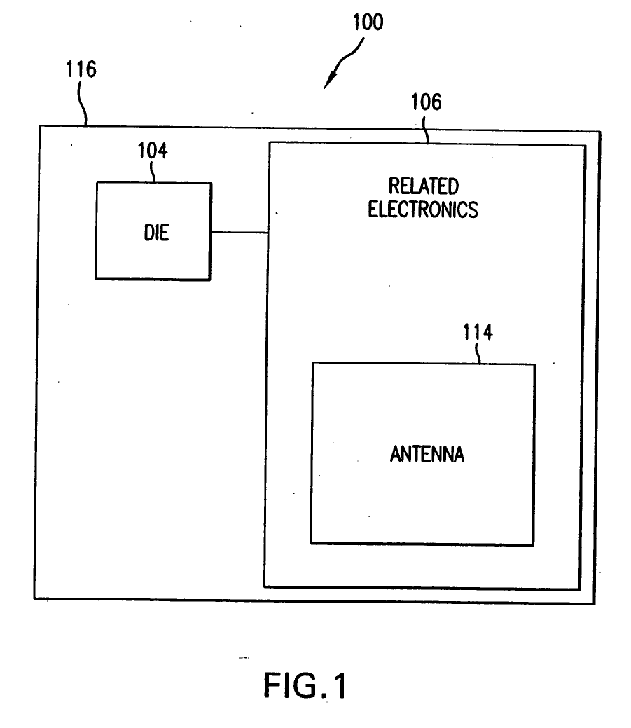

FIG. 1 shows a block diagram of an exemplary RFID tag 100, according to an embodiment of the present invention. As shown in FIG. 1, RFID tag 100 includes a die 104 and related electronics 106 located on a tag substrate 116. Related electronics 106 includes an antenna 114 in the present example. Die 104 can be mounted onto antenna 114 of related electronics 106, or on other locations of substrate 116. As is further described elsewhere herein, die 104 may be mounted in either a pads up or pads down orientation.

RFID tag 100 may be located in an area having a large number, population, or pool of RFID tags present. Tag 100 receives interrogation signals transmitted by one or more tag readers. According to interrogation protocols, tag 100 responds to these signals. The response(s) of tag 100 includes information that the reader can use to identify the corresponding tag 100. Once the tag 100 is identified, the existence of tag 100 within a coverage area defined by the tag reader is ascertained.

RFID tag 100 may be used in various applications, such as inventory control, airport baggage monitoring, as well as security and surveillance applications. Thus, tag 100 can be affixed to items such as airline baggage, retail inventory, warehouse inventory, automobiles, compact discs (CDs), digital video discs (DVDs), video tapes, and other objects. Tag 100 enables location monitoring and real time tracking of such items.

In the present embodiment, die 104 is an integrated circuit that performs RFID operations, such as communicating with one or more tag readers (not shown) according to various interrogation protocols. Exemplary interrogation protocols are described in U.S. Pat. No. 6,002,344 issued Dec. 14, 1999 to Bandy et al., titled “System and Method for Electronic Inventory,” and U.S. patent application Ser. No. 10/072,885, filed on Feb. 12, 2002, both of which are incorporated by reference herein in their entirety. Die 104 includes a plurality of contact pads that each provide an electrical connection with related electronics 106.

Related electronics 106 are connected to die 104 through a plurality of contact pads of IC die 104. In embodiments, related electronics 106 provide one or more capabilities, including RF reception and transmission capabilities, impedance matching, sensor functionality, power reception and storage functionality, as well as additional capabilities. The components of related electronics 106 can be printed onto a tag substrate 116 with materials, such as conductive inks. Examples of conductive inks include silver conductors 5000, 5021, and 5025, produced by DuPont Electronic Materials of Research Triangle Park, N.C. Other example materials or means suitable for printing related electronics 106 onto tag substrate 116 include polymeric dielectric composition 5018 and carbon-based PTC resistor paste 7282, which are also produced by DuPont Electronic Materials of Research Triangle Park, N.C. Other materials or means that may be used to deposit the component material onto the substrate would be apparent to persons skilled in the relevant art(s) from the teachings herein.

As shown in FIG. 1, tag substrate 116 has a first surface that accommodates die 104, related electronics 106, as well as further components of tag 100. Tag substrate 116 also has a second surface that is opposite the first surface. An adhesive material and/or backing can be included on the second surface. When present, an adhesive backing enables tag 100 to be attached to objects, such as books, containers, and consumer products. Tag substrate 116 is made from a material, such as polyester, paper, plastic, fabrics such as cloth, and/or other materials such as commercially available Tyvec®.

In some implementations of tags 100, tag substrate 116 can include an indentation, “cavity,” or “cell” (not shown in FIG. 1) that accommodates die 104. An example of such an implementation is included in a “pads up” orientation of die 104.

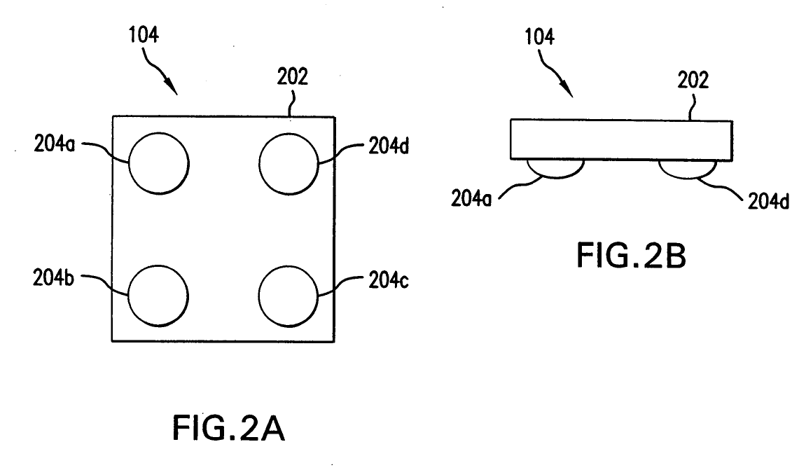

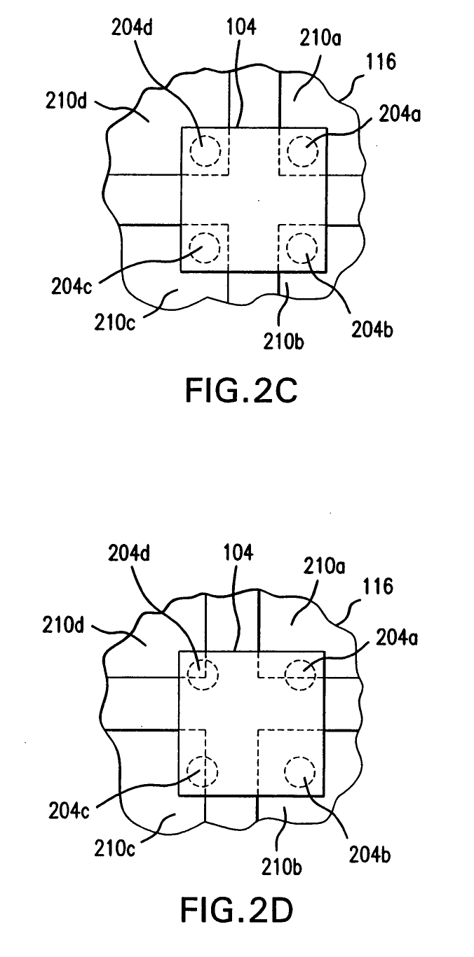

FIGS. 2A and 2B show plan and side views of an example die 104. Die 104 includes four contact pads 204a-d that provide electrical connections between related electronics 106 (not shown) and internal circuitry of die 104. Note that although four contact pads 204a-d are shown, any number of contact pads may be used, depending on a particular application. Contact pads 204 are typically made of an electrically conductive material during fabrication of the die. Contact pads 204 can be further built up if required by the assembly process, by the deposition of additional and/or other materials, such as gold or solder flux. Such post processing, or “bumping,” will be known to persons skilled in the relevant art(s).

FIG. 2C shows a portion of a substrate 116 with die 104 attached thereto, according to an example embodiment of the present invention. As shown in FIG. 2C, contact pads 204a-d of die 104 are coupled to respective contact areas 210a-b of substrate 116. Contact areas 210a-d provide electrical connections to related electronics 106. The arrangement of contact pads 204a-d in a rectangular (e.g., square) shape allows for flexibility in attachment of die 104 to substrate 116, and good mechanical adhesion. This arrangement allows for a range of tolerances for imperfect placement of IC die 104 on substrate 116, while still achieving acceptable electrical coupling between contact pads 204a-d and contact areas 210a-d. For example, FIG. 2D shows an imperfect placement of IC die 104 on substrate 116. However, even though IC die 104 has been improperly placed, acceptable electrical coupling is achieved between contact pads 204a-d and contact areas 210a-d.

Contact pads 204 can be attached to contact areas 210 of substrate 116 using any suitable conventional or other attachment mechanism, including solder, an adhesive material (including isotropic and anisotropic adhesives), mechanical pressure (e.g., being held in place by an encapsulating material), etc.

Note that although FIGS. 2A-2D show the layout of four contact pads 204a-d collectively forming a rectangular shape, a greater or lesser number of contact pads 204 may be used. Furthermore, contact pads 204a-d may be laid out in other shapes in other embodiments.

1.2 Device Assembly

The present invention is directed to continuous-roll assembly techniques and other techniques for assembling electronic devices, such as RFID tag 100. Such techniques involve a continuous web (or roll) of the material of the substrate 116 that is capable of being separated into a plurality of devices. Alternatively, separate sheets of the material can be used as discrete substrate webs that can be separated into a plurality of devices. As described herein, the manufactured one or more devices can then be post processed for individual use. For illustrative purposes, the techniques described herein are made with reference to assembly of tags, such as RFID tag 100. However, these techniques can be applied to other tag implementations and other suitable devices, as would be apparent to persons skilled in the relevant art(s) from the teachings herein.

The present invention advantageously eliminates the restriction of assembling electronic devices, such as RFID tags, one at a time, allowing multiple electronic devices to be assembled in parallel. The present invention provides a continuous-roll technique that is scalable and provides much higher throughput assembly rates than conventional pick and place techniques.

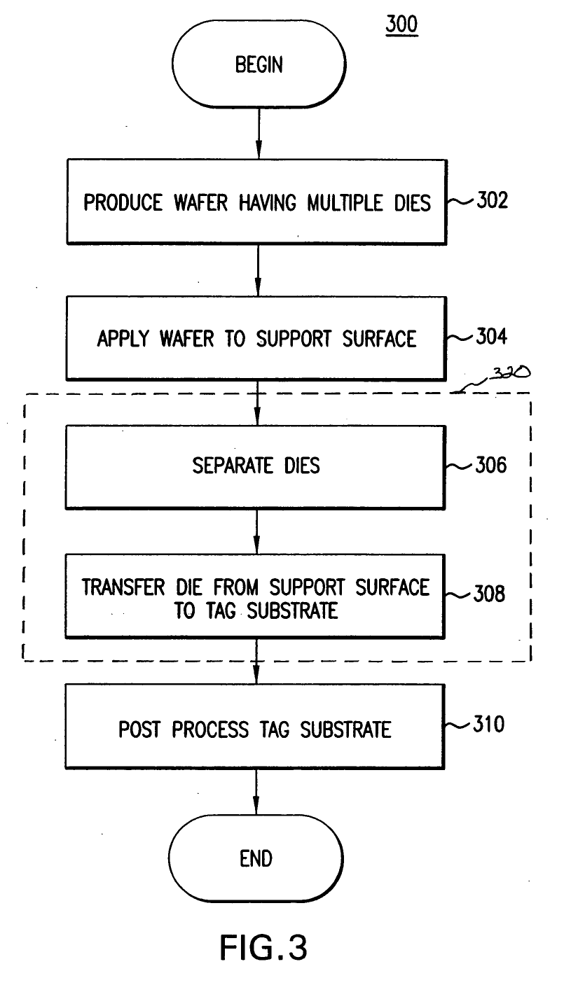

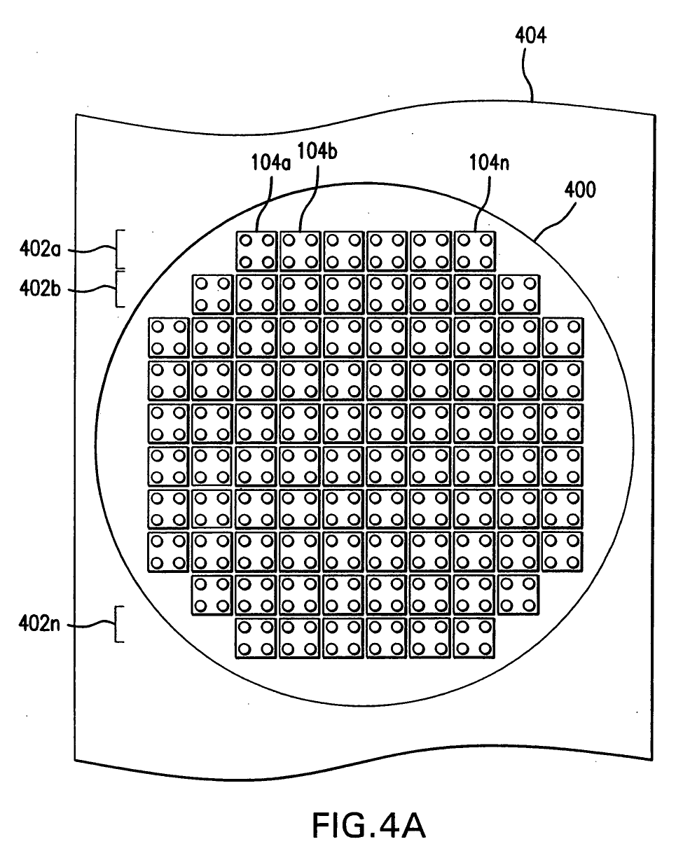

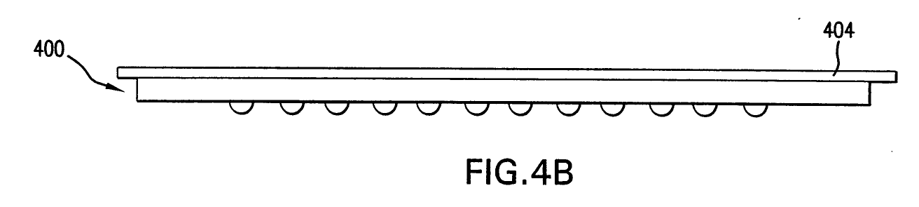

FIG. 3 shows a flowchart 300 with example steps relating to continuous-roll production of RFID tags 100, according to example embodiments of the present invention. FIG. 3 shows a flowchart illustrating a process 300 for assembling tags 100. The process 300 depicted in FIG. 3 is described with continued reference to FIGS. 4A and 4B. However, process 300 is not limited to these embodiments.

Process 300 begins with a step 302. In step 302, a wafer 400 (shown in FIG. 4A) having a plurality of dies 104 is produced. FIG. 4A illustrates a plan view of an exemplary wafer 400. As illustrated in FIG. 4A, a plurality of dies 104a-n are arranged in a plurality of rows 402a-n.

In a step 304, wafer 400 is optionally applied to a support structure or surface 404. Support surface 404 includes an adhesive material to provide adhesiveness. For example, support surface 404 may be an adhesive tape that holds wafer 400 in place for subsequent processing. For instance, in example embodiments, support surface 404 can be a “green tape” or “blue tape,” as would be understood by persons skilled in the relevant art(s). FIG. 4B shows an example view of wafer 400 in contact with an example support surface 404. In some embodiments, wafer 400 is not attached to a support surface, and can be operated on directly.

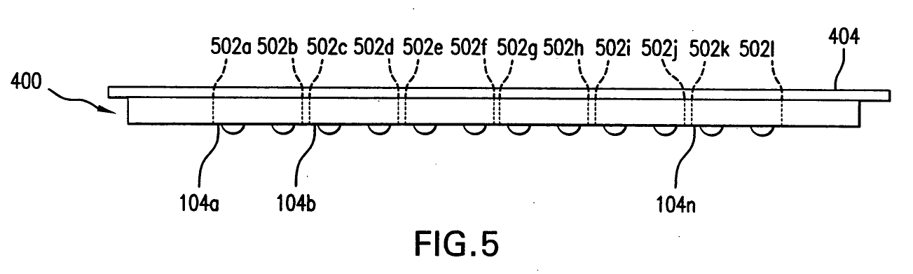

In a step 306, the plurality of dies 104 on wafer 400 are separated or “singulated”. For example, step 306 may include scribing wafer 400 using a wafer saw, laser etching, or other singulation mechanism or process. FIG. 5 shows a view of wafer 400 having example separated dies 104 that are in contact with support surface 404. FIG. 5 shows a plurality of scribe lines 502a-l that indicate locations where dies 104 are separated.

In a step 308, the plurality of dies 104 is transferred to a substrate. For example, dies 104 can be transferred from support surface 404 to tag substrates 116. Alternatively, dies 104 can be directly transferred from wafer 400 to substrates 116. In an embodiment, step 308 may allow for “pads down” transfer. Alternatively, step 308 may allow for “pads up” transfer. As used herein the terms “pads up” and “pads down” denote alternative implementations of tags 100. In particular, these terms designate the orientation of connection pads 204 in relation to tag substrate 116. In a “pads up” orientation for tag 100, die 104 is transferred to tag substrate 116 with pads 204a-204d facing away from tag substrate 116. In a “pads down” orientation for tag 100, die 104 is transferred to tag substrate 116 with pads 204a-204d facing towards, and in contact with tag substrate 116.

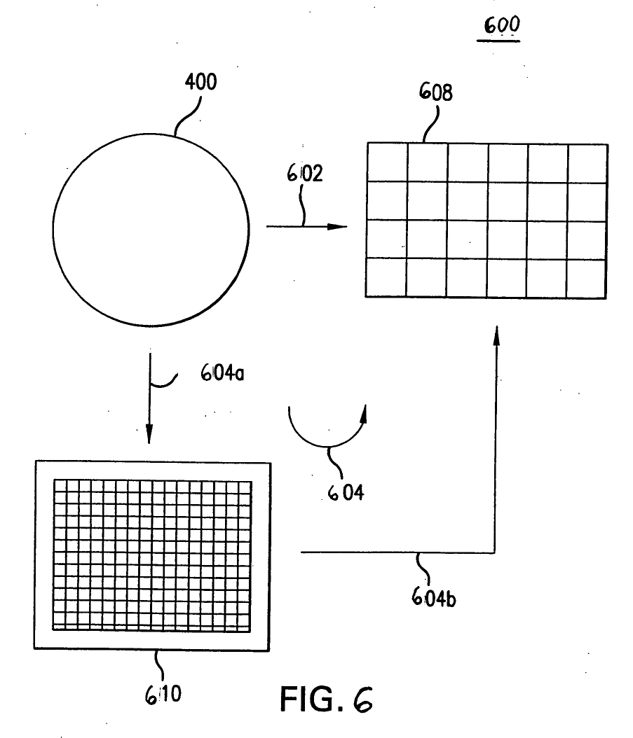

Note that step 308 may include multiple die transfer iterations. For example, in step 308, dies 104 may be directly transferred from a wafer 400 to substrates 116. Alternatively, dies 104 may be transferred to an intermediate structure, and subsequently transferred to substrates 116. Example embodiments of such die transfer options are described below in reference to FIG. 6.

Note that steps 306 and 308 can be performed simultaneously in some embodiments. This is indicated in FIG. 3 by step 320, which includes both of steps 306 and 308.

Example embodiments of the steps of flowchart 300, are described in co-pending applications, U.S. Ser. No. 10/866,148, titled “Method and Apparatus for Expanding a Semiconductor Wafer”; U.S. Ser. No. 10/866,150, titled “Method, System, and Apparatus for Transfer of Dies Using a Die Plate Having Die Cavities”; U.S. Ser. No. 10/866,253, titled “Method, System, and Apparatus for Transfer of Dies Using a Die Plate”; U.S. Ser. No. 10/866,159, titled “Method, System, and Apparatus for Transfer of Dies Using a Pin Plate”; and U.S. Ser. No. 10/866,149, titled “Method, System, and Apparatus for High Volume Transfer of Dies,” each of which is herein incorporated by reference in its entirety.

In a step 310, post processing is performed. For example, during step 310, assembly of RFID tag(s) 100 is completed. Example post processing of tags that can occur during step 310 are provided as follows:

(a) Separating or singulating tag substrates 116 from the web or sheet of substrates into individual tags or “tag inlays.” A “tag inlay” or “inlay” is used generally to refer to an assembled RFID device that generally includes a integrated circuit chip and antenna formed on a substrate.

(b) Forming tag “labels.” A “label” is used generally to refer to an inlay that has been attached to a pressure sensitive adhesive (PSA) construction, or laminated and then cut and stacked for application through in-mould, wet glue or heat seal application processes, for example. A variety of label types are contemplated by the present invention. In an embodiment, a label includes an inlay attached to a release liner by pressure sensitive adhesive. The release liner may be coated with a low-to-non-stick material, such as silicone, so that it adheres to the pressure sensitive adhesive, but may be easily removed (e.g., by peeling away). After removing the release liner, the label may be attached to a surface of an object, or placed in the object, adhering to the object by the pressure sensitive adhesive. In an embodiment, a label may include a “face sheet”, which is a layer of paper, a lamination, and/or other material, attached to a surface of the inlay opposite the surface to which the pressure sensitive material attaches. The face sheet may have variable information printed thereon, including product identification regarding the object to which the label is attached, etc.

(c) Testing of the features and/or functionality of the tags.

FIG. 6 further describes example flows for step 308 of FIG. 3. FIG. 6 shows a high-level system diagram 600 that provides a representation of the different modes or paths of transfer of dies from wafers to substrates. FIG. 6 shows a wafer 400, a substrate web 608, and a transfer surface 610. Two paths are shown in FIG. 6 for transferring dies, a first path 602, which is a direct path, and a second path 604, which is a path having intermediate steps.

For example, as shown in FIG. 6, first path 602 leads directly from wafer 400 to substrate web 608. In other words, dies can be transferred from wafer 400 to substrates of substrate web 608 directly, without the dies having first to be transferred from wafer 400 to another surface or storage structure. However, as shown in path 604, at least two steps are required, path 604A and path 604B. For path 604A, dies are first transferred from wafer 400 to an intermediate transfer surface 610. The dies then are transferred from transfer surface 610 via path 604B to the substrates of web 608. Paths 602 and 604 each have their advantages. For example, path 602 can have fewer steps than path 604, but can have issues of die registration, and other difficulties. Path 604 typically has a larger number of steps than path 602, but transfer of dies from wafer 400 to a transfer surface 610 can make die transfer to the substrates of web 608 easier, as die registration may be easier.

Any of the intermediate/transfer surfaces and final substrate surfaces may or may not have cells formed therein for dies to reside therein. Various processes described below may be used to transfer multiple dies simultaneously between first and second surfaces, according to embodiments of the present invention. In any of the processes described herein, dies may be transferred in either pads-up or pads-down orientations from one surface to another.

Elements of the die transfer processes described herein may be combined in any way, as would be understood by persons skilled in the relevant art(s). Example die transfer processes, and related example structures for performing these processes, are further described in the following subsections.

2.0 Die Transfer Embodiments

2.1 Changeable/Movable Material Embodiments

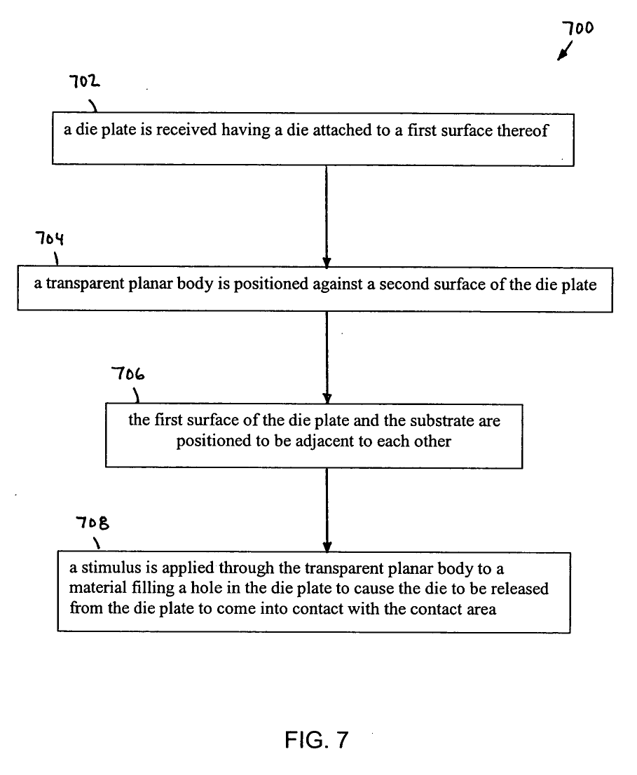

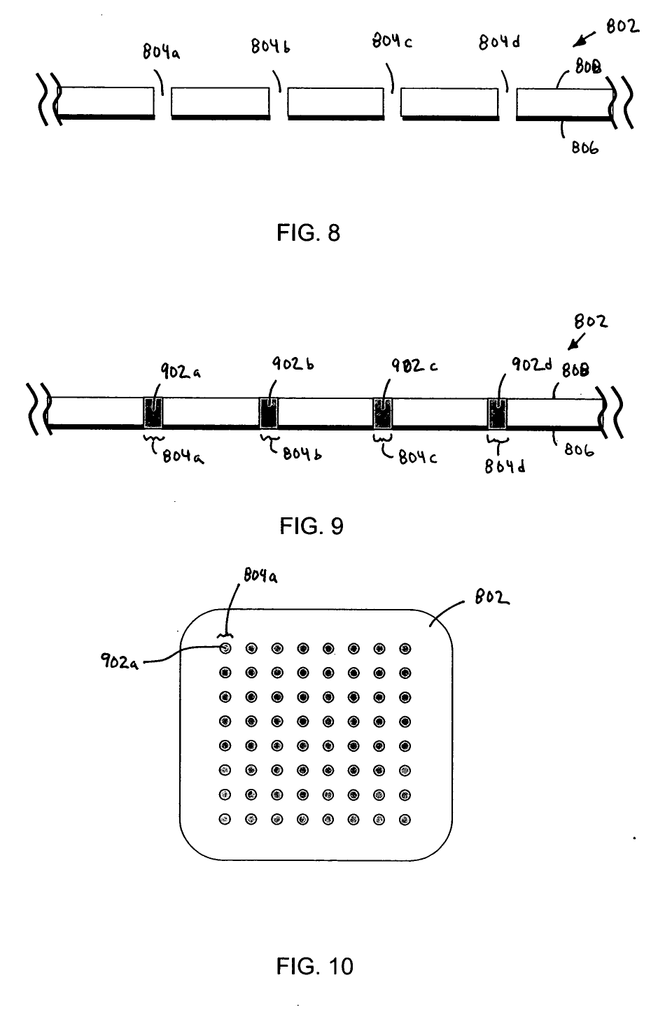

FIG. 7 shows a flowchart 700 of a method for transferring dies from an intermediate surface to a substrate using a changeable or movable material, according to embodiments of the present invention. The flowchart depicted in FIG. 7 is described with continued reference to FIGS. 8-13. However, flowchart 700 is not limited to those embodiments. Further operational and structural embodiments of the present invention will be apparent to persons skilled in the relevant arts based on the following discussion. Note that in alternative embodiments, steps shown in FIG. 7 can occur in an order other than that shown, and in some embodiments, not all steps shown are necessary.

Flowchart 700 begins at step 702. In step 702, a die plate is received having a die attached to a first surface thereof. For example, the die plate is die plate 802 shown in FIG. 8. FIG. 8 shows a cross-sectional view of die plate 802, according to an example embodiment of the present invention. As shown in FIG. 8, die plate 802 has a plurality of holes 804 extending from a first surface 806 to a second surface 808 of die plate 802. Example embodiments of die plates are described in co-pending applications, U.S. Ser. No. 10/866,150, titled “Method, System, and Apparatus for Transfer of Dies Using a Die Plate Having Die Cavities,” (Atty. Dkt. 1689.0540000) and U.S. Ser. No. 10/866,253, titled “Method, System, and Apparatus for Transfer of Dies Using a Die Plate,” (Atty. Dkt. 1689.0550000), both of which are herein incorporated by reference in their entireties.

Although not shown in FIG. 8, die plate 802 can be supported by a die plate holder, which may include a clamp, or other mechanism for holding die plate 802.

Furthermore, as shown in FIGS. 9 and 10, each hole 804 in die plate 802 is filled with a material 902. FIG. 9 shows a cross-sectional view of die plate 802, while FIG. 10 shows a plan view of die plate 802, according to example embodiment of the present invention. For example, as shown in FIG. 9, hole 804a is filled with a material 902a. Example embodiments for material 902 are described below.

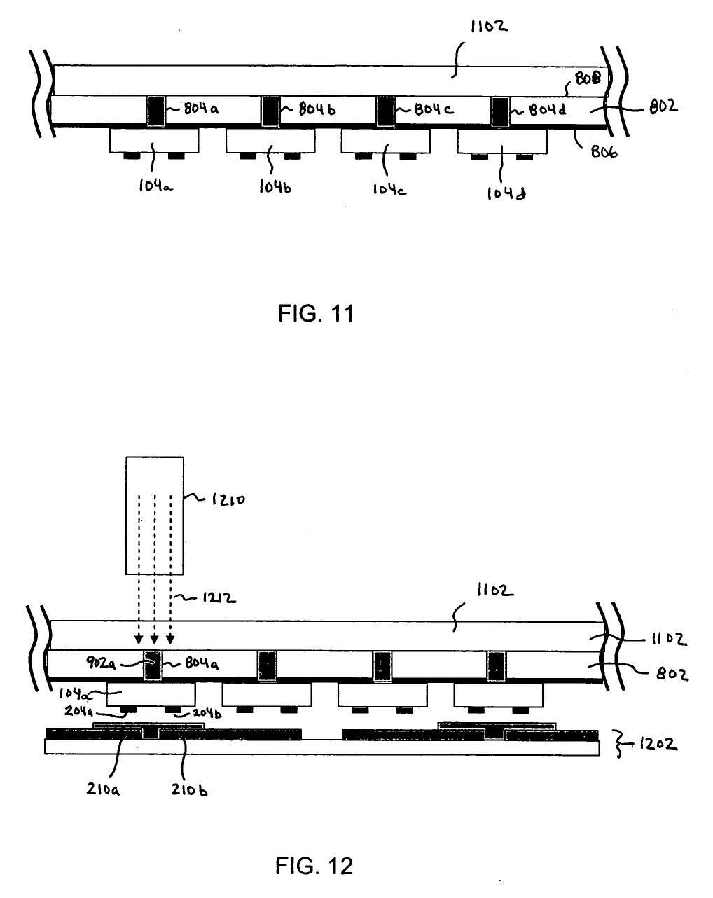

In step 704, a transparent planar body is positioned against a second surface of the die plate. For example, FIG. 11 shows a transparent planar body 1102 positioned against second surface 808 of die plate 802. Transparent planar body 1102 can be made from any suitable transparent material, including glass, crystal, or a transparent mineral such as quartz.

FIG. 11 further shows die plate 802 having a plurality of dies 104 attached to first surface 806 of die plate 802. As shown in FIG. 11, each die 104 covers a corresponding hole 804 through die plate 802 at first surface 806 of die plate 802.

In step 706, the first surface of the die plate and the substrate are positioned to be adjacent to each other. For example, FIG. 12 shows die plate 802 and substrate 1202 positioned to be adjacent to each other such that contact pads 204a and 204b of die 104a are closely adjacent to corresponding contact areas 210 of a tag substrate 1204a of substrate 1202. Note that die plate 802 and substrate 1202 in various embodiments can be positioned to varying degrees of closeness to each other, including distances other than that shown in FIG. 12.

In step 708, a stimulus is applied through the transparent planar body to a material filling a hole in the die plate to cause the die to be released from the die plate to come into contact with the contact area. FIG. 12 shows a stimulus source 1210 applying an example stimulus 1212. Example stimuli that can be used are heating, application of a voltage, application of a current, application of a force, or application of other stimulus or combination thereof. The stimulus used is determined based on the physics and/or characteristics of the material used to fill the holes of the die plate. For example, the material can be caused to expand, exert pressure, or move in the hole. This action by the material releases each die of the plurality of dies from the die plate.

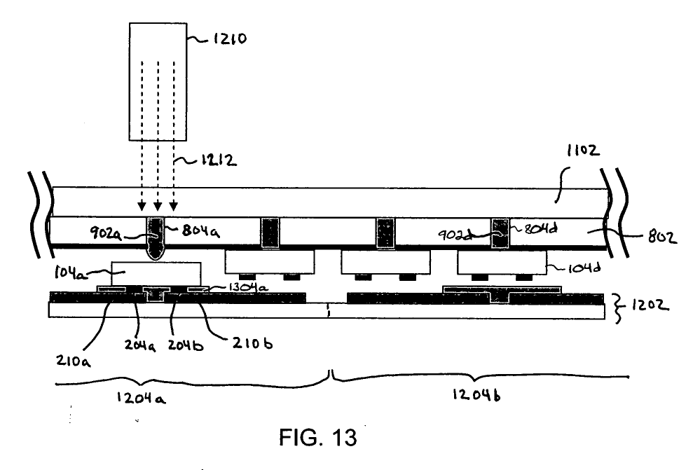

For example, FIG. 13 shows material 902a that is caused to expand in hole 804a by stimulus 1212. By expanding, material 902a detaches die 104a from bottom surface 806 of die plate 802. Thus, die 104a is moved by material 902a to contact with substrate 1204a.

Furthermore, transparent planar body 1102 prevents material 902a from expanding upward. Thus, material 902a can only expand downward, toward die 104a. Furthermore, because transparent planar body 1102 is transparent, a light-based stimulus can be used, being directed on material 902a through transparent planar body 1102.

For example, in FIG. 13, stimulus source 1210 may be a laser that causes material 902a filling hole 804a to expand. In such an embodiment, stimulus 1212 is a laser beam/laser light directed towards material 902a, which heats material 902a to cause it to expand. Stimulus source 1210 can be a scanning laser, for example, to scan over die plate 802 to move further dies 104 from die plate 802 onto substrates 1204. For example, after causing die 104a to be transferred, stimulus source 1210 could be directed on die 104d to cause material 902d filling hole 804d to expand, to transfer die 104d onto substrate 1204b.

In an embodiment, a computer system is used to control systems of the present invention. For example, the computer system may be configured to control movement of a die plate holder to position die plate 802 adjacent to substrate 1202. Furthermore, the computer system may be configured to control a substrate supply, which may be supplying substrates singly or in web format (i.e., sheets or continuous roll of substrates). Still further, the computer system may be configured to control stimulus source 1210 (e.g., a laser), to actuate the stimulus, and to direct the stimulus to various positions on die plate 802 to cause dies 104 to be transferred therefrom.

Note that in alternative embodiments, other methods may be used to cause material 902 to expand. In this manner, an expandable material can be used to transfer dies from a die plate, in place of the use of punch pins of a pin plate.

Furthermore, FIG. 13 also shows an adhesive material 1304a adhering contact pads 204 of die 104 to the corresponding contact areas 210 on the first surface of substrate 1204a. In an embodiment, the adhesive material 1304a can be cured or otherwise treated to cause die 104a to adhere to substrate 1204a.

Material 902 can be any material that can be caused to expand or contract when exposed to stimuli, including an epoxy, a plastic, a polymer, a glass, or other material or combination thereof. Alternatively, the material can be any material that can be caused to exert pressure in multiple directions or change positions when exposed to stimuli including a magnetic fluid, artificial muscle material, or other material or combination thereof.

For example, material 902 can be a material having a high coefficient of expansion, including a metal, polymer, or plastic. Material 902 can be a material that changes phases upon application of a stimulus, changing from solid to liquid, or from liquid to gas. For example, material 902 could be water, which is caused by stimulus source 1210 to change phase to gas, causing an expansive pressure. Material 902 can be a micro-encapsulated gas, such as hydrogen peroxide. In an embodiment, the expansion of material 902 over time can be controlled, to maintain a downward force as desired for a particular application. For example, the expansion of material 902 can be controlled to avoid damaging integrated circuit dies, or avoid causing transparent planar body 1102 to become separated from die plate 802.

Referring to FIG. 13, material 902 in holes 804 of die plate 802 can be selectively stimulated by using a mask, for example. The mask is positioned between stimulus source 1210 and die plate 802. The mask can be configured to cover selected holes 804 of die plate 802. The mask prevents stimulus 1212 from expanding material 902 in a hole 804 that is covered by the mask. The mask can include a reflective and/or absorptive material. For example, the reflective and/or absorptive material can prevent a laser beam/laser light from illuminating material 902 in a hole 804 that is covered by the mask.

2.2 Selective Transfer Embodiments

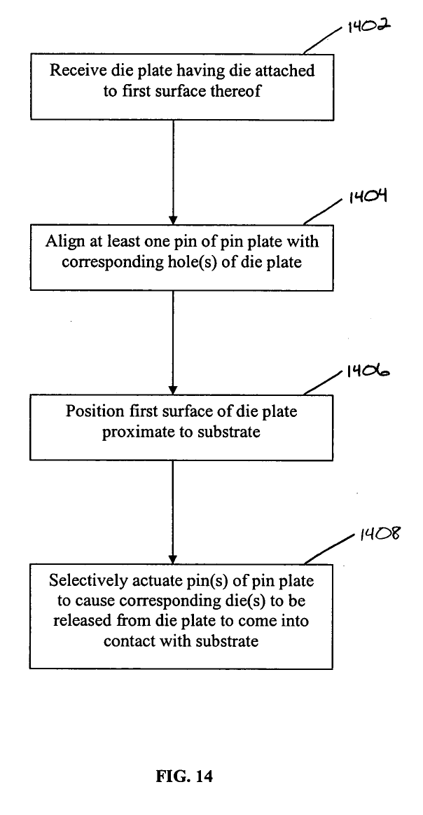

FIG. 14 shows a flowchart 1400 of a method for selectively transferring die(s) from an intermediate surface to a substrate, according to embodiments of the present invention. According to flowchart 1400, dies are selectively transferred by individually actuated pins. Any one or more of the dies can be transferred to the substrate by corresponding actuated pin(s).

The flowchart depicted in FIG. 14 is described with continued reference to FIGS. 8 and 15-30. However, flowchart 1400 is not limited to those embodiments. Further operational and structural embodiments of the present invention will be apparent to persons skilled in the relevant arts based on the following discussion. Note that in alternative embodiments, steps shown in FIG. 14 can occur in an order other than that shown, and in some embodiments, not all steps shown are necessary.

Flowchart 1400 begins at step 1402. In step 1402, a die plate is received having a die attached to a first surface thereof. For example, the die plate is die plate 802, as described above with reference to FIG. 8. Dies can be attached to die plate 802 as described above with reference to FIG. 11, for example.

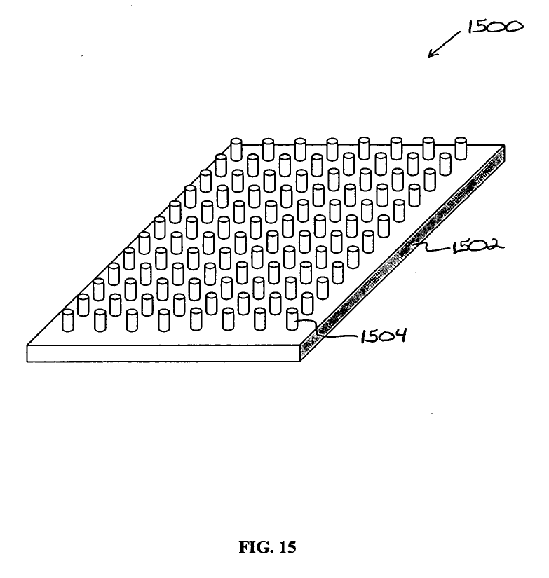

In step 1404, at least one pin of a pin plate is aligned with corresponding hole(s) of the die plate. FIG. 15 shows an example pin plate 1500, according to an embodiment of the present invention. Pin plate 1500 can be referred to by a variety of other names, including nail plate, “bed-of-nails,” and punch plate.

As shown in FIG. 15, pin plate 1500 includes a body 1502. Body 1502 is shown in FIG. 15 as a substantially planar structure, but can have other shapes. Furthermore, while the planar surfaces of body 1502 are shown to be square or rectangular in shape, body 1502 can have other shapes, including circular, elliptical, hexagonal, cross-shaped, and diamond shaped. As shown in FIG. 15, body 1502 has a plurality of nails or pins 1504 extending from a first surface thereof. Pins 1504 are typically arranged in an array of rows and columns of pins. In FIG. 15, pins 1504 are configured in an array of twelve rows and eight columns for illustrative purposes. Pin plate 1500 can be made from any number of materials, including a metal or combination of metals/alloy, a polymer, a plastic, glass, another material, and any combination thereof.

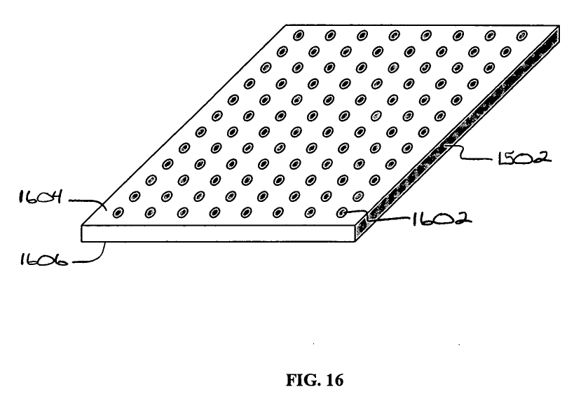

According to an embodiment, and as further described below, pins 1504 are retracted at least partially within body 1502. In FIG. 16, body 1502 includes openings or holes 1602 through which pins 1504 are retracted and/or extended. In an embodiment, holes 1602 are open from a first surface 1604 of body 1502 to a second surface 1606 of body 1502. In an alternative embodiment, holes 1602 do not extend entirely through body 1502. For instance, holes 1602 can extend from first surface 1604 partially through body 1502.

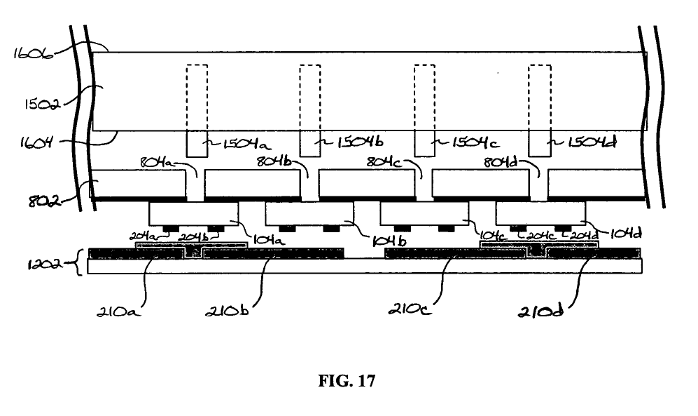

In step 1406, the first surface of the die plate is positioned proximate to the substrate. For example, FIG. 17 shows die plate 802 positioned in close proximity with substrate 1202 such that contact pads 204a and 204b of die 104a are closely adjacent to corresponding contact areas 210a and 210b of tag substrate 1204a of substrate 1202, and contact pads 204c and 204d of die 104b are closely adjacent to corresponding contact areas 210c and 210d of tag substrate 1204b. Note that die plate 802 and substrate 1202 in various embodiments can be positioned to varying degrees of closeness to each other, including distances other than that shown in FIG. 17.

FIG. 17 further shows pins 1504 of pin plate 1500 aligned with corresponding holes 804 of die plate 802, as described above with respect to step 1404. Although pins 1504a-d are all shown to be aligned with corresponding holes 804a-d of die plate 802, the scope of the invention is not limited in this respect. For instance, it may be sufficient for a single pin 1504 to be aligned with a corresponding hole 804 of die plate 802. In embodiments, surface 1604 of pin plate 1500 can be spaced from, or in contact with, die plate 802.

In step 1408, at least one pin of the pin plate is selectively actuated to cause corresponding die(s) to be released from the die plate to come into contact with the substrate. Various example actuator embodiments are described in the following paragraphs.

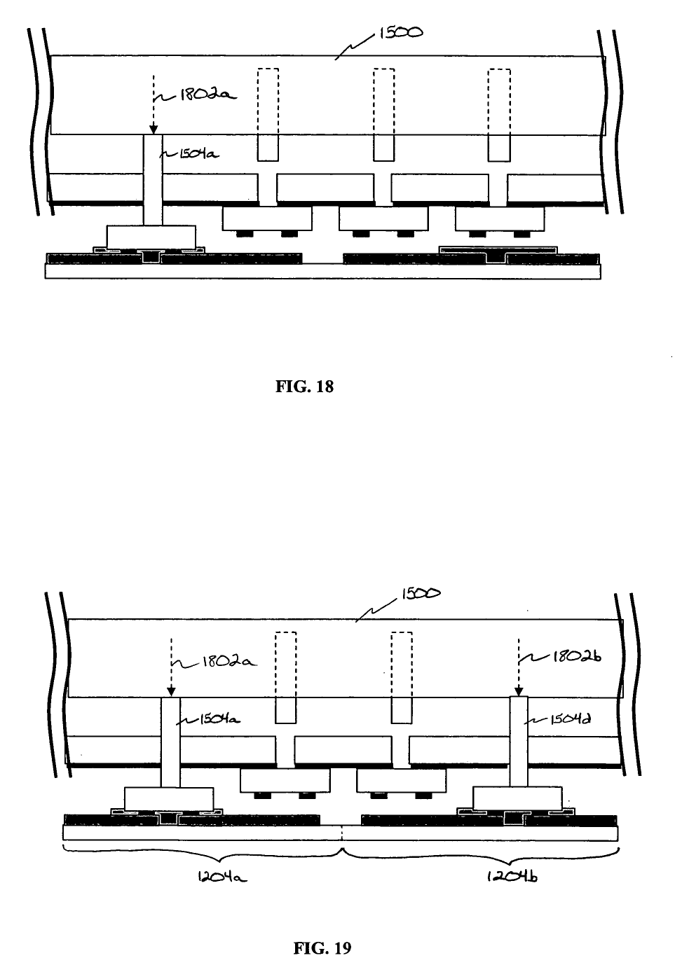

FIG. 18 shows an actuator 1802a selectively applied to pin 1504a of pin plate 1500. Example actuators that can be used include heating, application of a voltage, application of a current, application of a force, or application of other stimulus or combination thereof. Selectively actuating pin 1504a extends pin 1504a from corresponding hole 1602 of body 1502, thereby releasing die 104a from die plate 802.

FIG. 19 illustrates that multiple pins can be selectively actuated. For example, stimuli 1802a and 1802b are selectively applied to respective pins 1504a and 1504d. Dies 104a and 104d are released from die plate 802 and deposited onto substrates 1204a and 1204b, respectively. In an alternative embodiment, dies 104a and 104b are deposited onto the same substrate 1204a or 1204b. According to an embodiment, multiple pins 1504, such as pins 1504a and 1504d in FIG. 19, are simultaneously selectively actuated. In an embodiment, pin(s) 1504 are retracted back to their non-extended positions after corresponding die(s) 104 are released from die plate 802.

Various example actuator embodiments are described in the following text that can be used to perform step 1408 of FIG. 14.

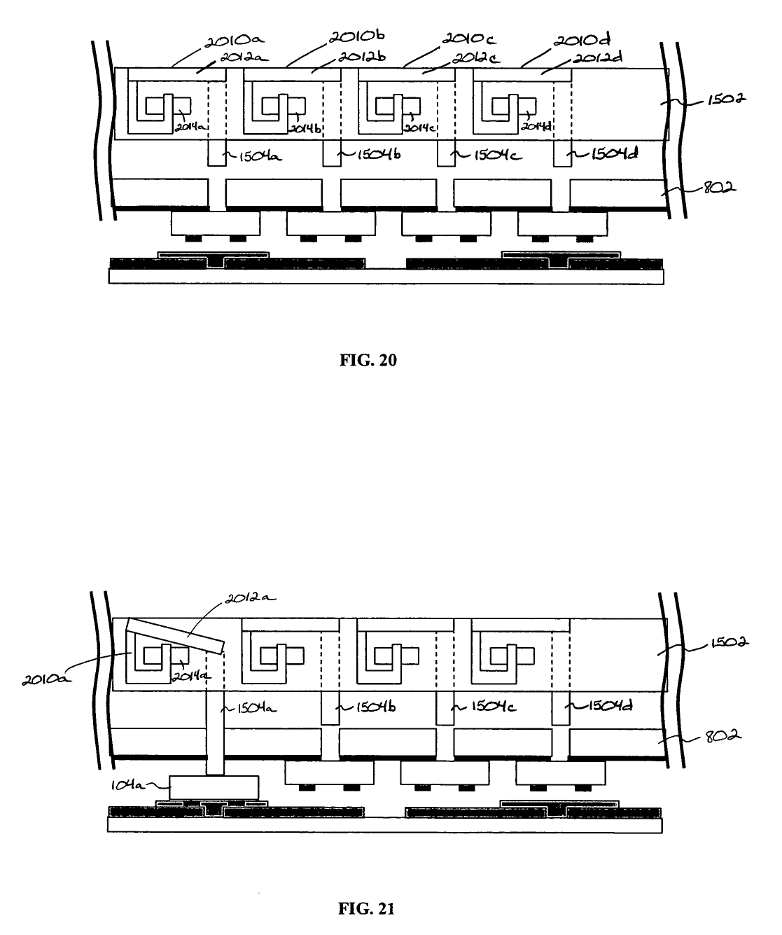

FIG. 20 shows example actuators 2010a-d coupled to respective pins 1504a-d of pin plate 1500, according to an embodiment of the present invention. Actuators 2010a-d each include a respective arm 2012a-d and a respective coil 2014a-d. Each arm 2012a-d is coupled to a respective pin 1504a-d. In FIG. 20, pins 1504a-d are shown in non-extended positions. An electrical current is selectively supplied to at least one coil 1504 to generate an electromagnetic field. The electromagnetic field causes corresponding arm(s) to rotate toward the at least one coil 1504. For example, FIG. 21 shows pin 1504a selectively actuated, according to an embodiment of the present invention. In FIG. 21, a current is selectively supplied to coil 2014a, causing an electromagnetic field to attract arm 2012a toward coil 2014a. When arm 2012a rotates toward coil 2014a, pin 1504a is extended through a corresponding hole 1602 in body 1502, releasing die 104a from die plate 802

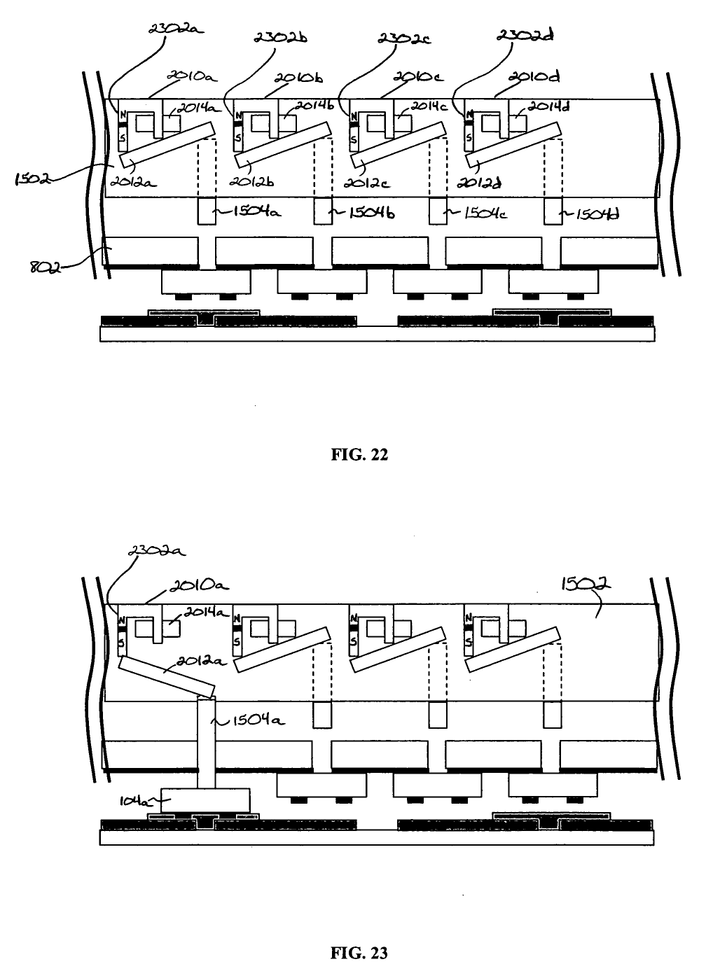

FIG. 22 shows example actuators 2010a-d coupled to respective pins 1504a-d of pin plate 1500, according to another embodiment of the present invention. In the embodiment of FIG. 22, actuators 2010a-d each include a respective coil 2014a-d, arm 2012a-d, and permanent magnet 2302a-d. Permanent magnets 2302a-d each generate a magnetic field that holds respective arm 2012a-d in a stressed position, as shown in FIG. 22. In the stressed position, arms 2012a-d are rotated toward respective coils 2014a-d, thereby retracting pins 1504a-d in respective holes 1602 of body 1502.

FIG. 23 shows pin 1504a selectively actuated, according to another embodiment of the present invention. In FIG. 23, an electrical current is selectively supplied to coil 2014a, creating an electromagnetic field that opposes the magnetic field generated by permanent magnet 2302a. Arm 2012a rotates away from coil 2014a to extend pin 1504a through corresponding hole 1602 of body 1502, thereby releasing die 104a from die plate 802.

According to an embodiment, springs are coupled to respective arms 2012a-d of actuators 2010a-d. For example, holding arms 2012a-d in stressed positions can provide tension to respective springs. Referring to FIG. 23, when pin 1504a is selectively actuated, tension of the corresponding spring causes rotation of arm 2012a away from coil 2014a.

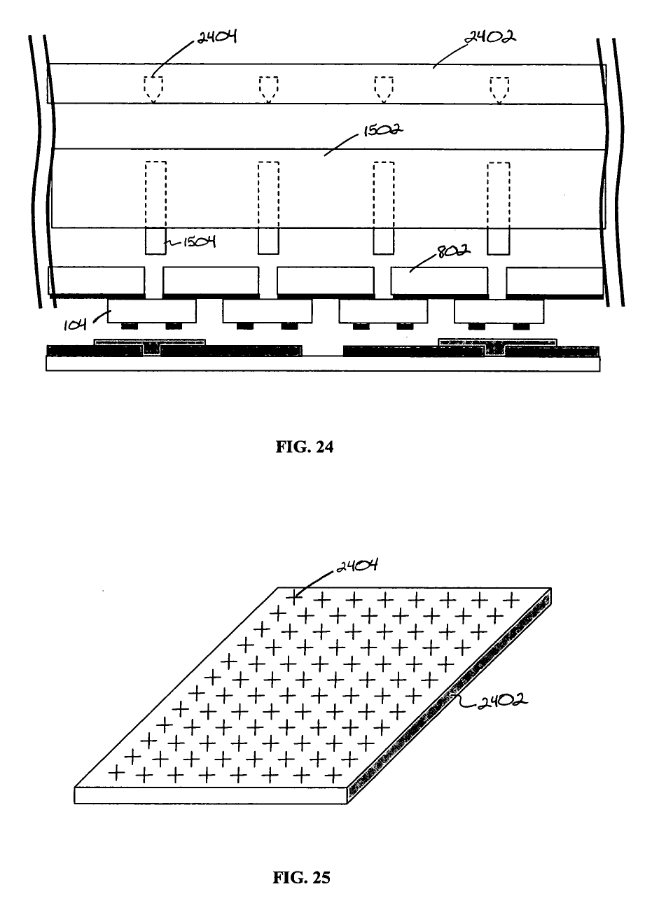

FIG. 24 shows another example actuation mechanism, according to an embodiment of the present invention. FIG. 24 shows a stimulus plate 2402 having stimulators 2404, according to an embodiment of the present invention. Stimulator(s) 2404 are selectively activated, depending on which die(s) 104 are to be released from die plate 802. According to an embodiment, stimulators provide stimuli to actuators in pin plate 1502. For example, a stimulator 2404 can selectively provide a current to a coil 2014 of an actuator 2010 as described above with respect to FIGS. 20-23. In an alternative embodiment, a stimulator 2404 selectively supplies a stimulus directly to a pin 1504 of pin plate 1500.

FIG. 25 shows a perspective view of stimulus plate 2402, corresponding to pin plate 1500 shown in FIG. 15, according to an embodiment of the present invention. Each stimulator 2404 corresponds to a respective pin 1504 of pin plate 1500. Pins 1504 can be selectively stimulated by programming respective stimulators 2404 to supply stimuli to respective pins 1504. Stimulators 2404 can be programmed using software, firmware, hardware, or any combination thereof. Stimulus plate 2402 can have stimulators 2404 configured in any number of rows and/or columns, or in any other suitable configuration. According to an embodiment, stimulus plate 2402 selectively stimulates pins 1504 by moving along pin plate 1500.

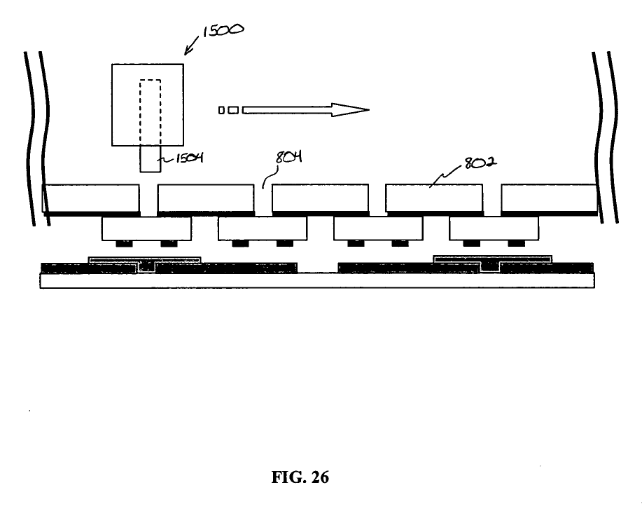

As shown in FIG. 26, the configuration of pins 1504 in pin plate 1500 need not necessarily correspond to the configuration of holes 804 in die plate 802. FIG. 26 shows pin plate 1500 having a single column of pins 1504, though the scope of the invention is not limited in this respect. Pin plate 1500 can have pins 1504 configured in any number of rows and/or columns, or in any other suitable configuration.

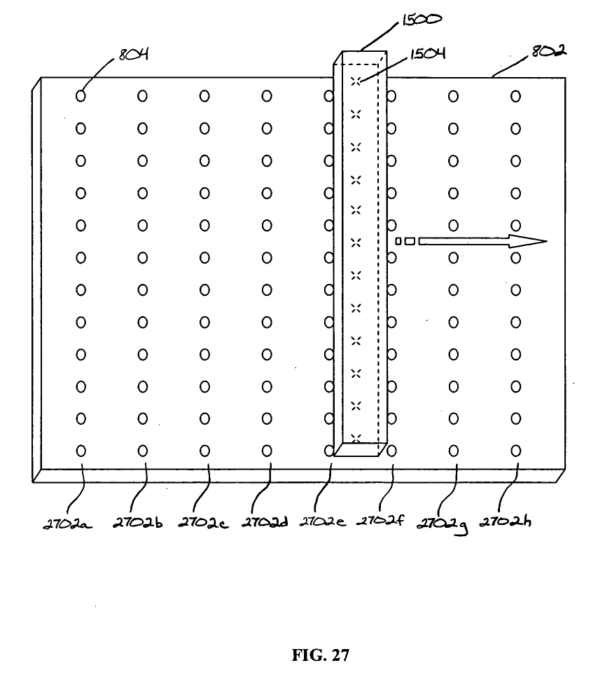

FIG. 27 illustrates a pin plate, such as pin plate 1500, in which pins 1504 are selectively actuated as the pin plate is moved across die plate 802. In FIG. 27, pins 1504 are selectively moved into holes 804 of die plate 802 one row at a time. For example, pin plate 1500 is positioned adjacent to row 2702a, such that pins 1504 can be selectively moved into holes 804 in row 2702a. Pin plate 1500 is then positioned adjacent to row 2702b, such that pins 1504 can be selectively moved into holes 804 in row 2702b, and so on. According to an embodiment, pin plate 1500 need not necessarily be positioned adjacent to all rows 2702 of holes 804. For example, a row 2702 may be bypassed if no pins 1504 are to be selectively moved into holes 804 in that row 2702.

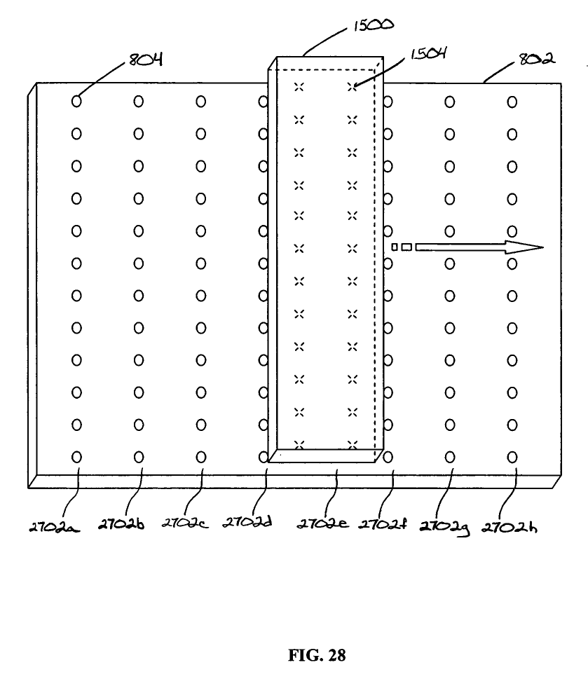

FIG. 28 shows a pin plate 1500 having two columns of pins 1504, according to another embodiment of the present invention. In FIG. 28, pins 1504 are selectively moved into holes 804 two rows at a time. For example, pin plate 1500 is positioned adjacent to rows 2702a and 2702b, such that pins 1504 can be selectively moved into holes 804 in rows 2702a and 2702b. Pin plate 1500 is then positioned adjacent to rows 2702c and 2702d, such that pins 1504 can be selectively moved into holes 804 in rows 2702c and 2702d, and so on.

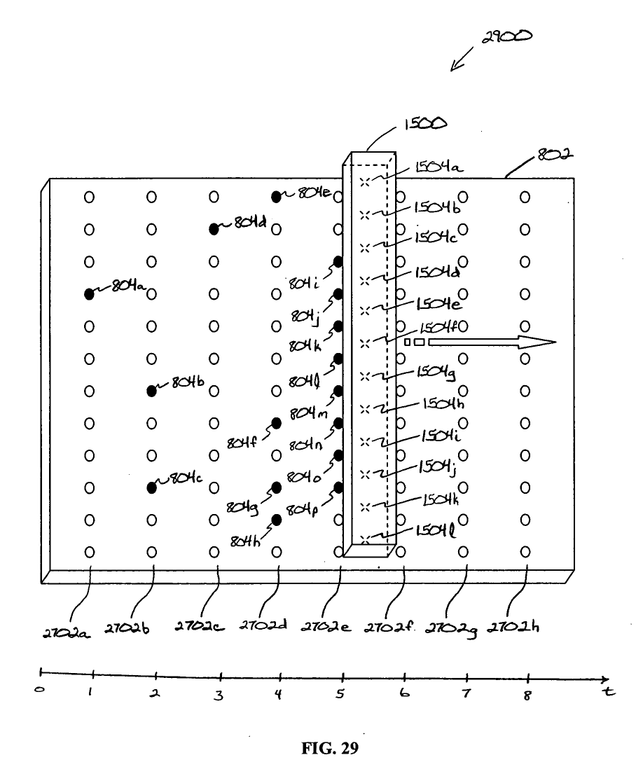

FIG. 29 illustrates a system 2900 in which pins 1504 of pin plate 1500 are selectively actuated as pin plate 1500 moves across die plate 802, according to an embodiment of the present invention. At time t=1, pin 1504d is selectively actuated, such that pin 1504d moves into hole 804a in column 2702a. At time t=2, pins 1504g and 1504j are selectively actuated, such that pins 1504g and 1504j move into holes 804b and 804c, respectively, in column 2702b. At time t=3, pin 1504b is selectively actuated, such that pin 1504b moves into hole 804d in column 2702c. At time t=4, pins 1504a, h, j, and k are selectively actuated, such that pins 1504a, h, j, and k move into holes 804e-h, respectively, in column 2702d. At time t=5, pins 1504c-j are selectively actuated, such that pins 1504c-j move into holes 804i-p, respectively, in column 2702e.

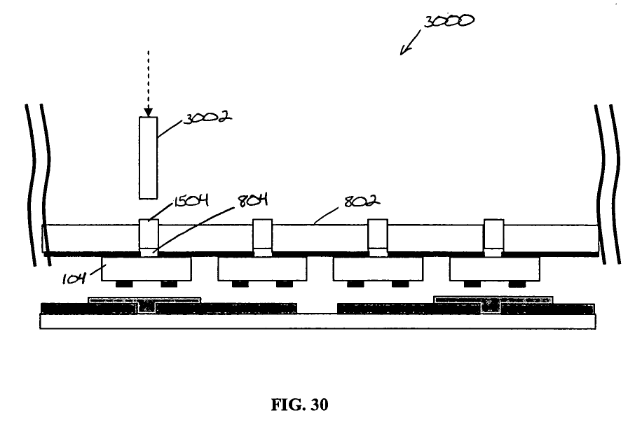

FIG. 30 shows a system 3000 in which pins 1504 are included in holes 804 of die plate 802, according to an embodiment of the present invention. For example, including pins 1504 in holes 804 of die plate 802 can eliminate the need for a pin plate, such as pin plate 15 described above with respect to FIG. 15. In FIG. 30 an actuator 3002 selectively actuates a pin 1504 by displacing the pin 1504 in its corresponding hole 804. Actuator 3002 causes an actuated pin 1504 to exert a force upon a corresponding die 104, thereby releasing the die 104 from die plate 802. Actuator 3002 can selectively displace a pin 1504 by using force, pressure, voltage, current, illumination, or any other suitable means.

3.0 Other Embodiments

FIGS. 1-30 are conceptual illustrations allowing an easy explanation of transferring die(s) from an intermediate surface to a substrate. It should be understood that embodiments of the present invention can be implemented in hardware, firmware, software, or a combination thereof. In such an embodiment, the various components and steps are implemented in hardware, firmware, and/or software to perform the functions of the present invention. That is, the same piece of hardware, firmware, or module of software can perform one or more of the illustrated blocks (i.e., components or steps).

In this document, the terms “computer program medium” and “computer usable medium” are used to generally refer to media such as a removable storage unit, a hard disk installed in hard disk drive, and signals (i.e., electronic, electromagnetic, optical, or other types of signals capable of being received by a communications interface). These computer program products are means for providing software to a computer system. The invention, in an embodiment, is directed to such computer program products.

In an embodiment where aspects of the present invention are implemented using software, the software may be stored in a computer program product and loaded into computer system using a removable storage drive, hard drive, or communications interface. The control logic (software), when executed by a processor, causes the processor to perform the functions of the invention as described herein.

According to an embodiment, a computer executes computer-readable instructions to control the release of die(s) from an intermediate surface, such as die plate 802, to a substrate. For instance, a roll of substrate material may be provided. The computer controls stimulation of a material (e.g., material 902) or actuation of an actuator to cause one or more dies to be released from the intermediate surface to a first portion of the substrate. The roll of substrate may be advanced to provide a second portion of the substrate. The computer controls stimulation or actuation to cause one or more dies to be released from the intermediate surface to the second portion of the substrate, and so on. In an embodiment, the computer executes instructions to selectively stimulate the material or selectively actuate the actuator.

In another embodiment, aspects of the present invention are implemented primarily in hardware using, for example, hardware components such as application specific integrated circuits (ASICs). Implementation of the hardware state machine so as to perform the functions described herein will be apparent to one skilled in the relevant art(s).

In yet another embodiment, the invention is implemented using a combination of both hardware and software.

4.0 Conclusion

While various embodiments of the present invention have been described above, it should be understood that they have been presented by way of example, and not limitation. It will be apparent to persons skilled in the relevant arts that various changes in form and detail can be made therein without departing from the spirit and scope of the invention. Thus the present invention should not be limited by any of the above-described exemplary embodiments, but should be defined only in accordance with the following claims and their equivalents.

What is claimed is:

1. A method for transferring a plurality of integrated circuit dies from a die plate to a substrate, comprising:
(a) receiving a die plate that has a first surface having a die attached thereto, wherein the die covers a corresponding hole through the die plate;
(b) positioning a transparent planar body against a second surface of the die plate;
(c) positioning the first surface of the die plate and the substrate to be adjacent to each other such that the die is closely adjacent to a corresponding contact area on a first surface of the substrate; and
(d) applying a stimulus through the transparent planar body to a material filling the hole in the die plate to cause the die to be released from the die plate to come into contact with the contact area.

2. The method of claim 1, wherein the stimulus is selectively applied through the transparent planar body.

3. The method of claim 2, further comprising:
(e) covering another hole in the die plate using a mask.

4. The method of claim 1, wherein step (a) includes:
receiving the die plate having the hole empty;
filling the empty hole with the material; and
positioning the die onto the first surface of the die plate over the hole filled with the material.

5. The method of claim 1, wherein step (a) includes:
receiving the die plate having the hole empty;
positioning the die onto the first surface of the die plate over the empty hole; and
filling the empty hole with the material.

6. The method of claim 1, wherein step (a) includes:
receiving the die plate having a plurality of dies attached to the first surface of the die plate, the die plate having a plurality of holes therethrough, wherein each die of the plurality of dies covers a corresponding hole through the die plate.

7. The method of claim 6, further comprising:
(e) repeating step (d) on each die of the plurality of dies to cause each die to be released from the die plate to come into contact with a corresponding contact area on the substrate.

8. The method of claim 1, wherein step (d) includes:
using a laser to heat the material through the transparent planar body to cause the material to expand, thereby causing the die to be released from the die plate.

9. A system for transferring integrated circuit dies, comprising:
a die plate holder configured to mount a die plate, said die plate having a first surface having a die attached thereto, wherein the die covers a corresponding hole through the die plate;
a transparent planar body configured to be positioned against a second surface of the die plate;
a substrate supply configured to present a substrate, wherein the die plate holder is further configured to position the first surface of the die plate adjacent to the substrate such that the die is closely adjacent to a corresponding contact area on a first surface of the substrate; and
a stimulus source configured to apply a stimulus through the transparent planar body to a material filling the hole in the die plate to cause the die to be released from the die plate to come into contact with the contact area.

10. The system of claim 9, wherein the stimulus source is a laser.

11. The system of claim 9, wherein said die plate has a plurality of dies attached to the first surface of the die plate, the die plate having a plurality of holes therethrough, wherein each die of the plurality of dies covers a corresponding hole through the die plate, wherein the material fills each hole in the die plate;
wherein said stimulus source is configured to apply a stimulus through the transparent planar body to the material filling each hole in the die plate to cause each die to be released from the die plate to come into contact with a corresponding contact area of the substrate.

12. A method of transferring a plurality of integrated circuit dies from a die plate to a substrate, comprising:
(a) receiving a die plate that has a first surface having a die attached thereto, wherein the die covers a corresponding hole in the die plate;
(b) aligning a pin with the hole in the die plate;
(c) positioning the first surface of the die plate and the substrate to be adjacent to each other such that the die is closely adjacent to a corresponding contact area on a first surface of the substrate; and
(d) selectively actuating the pin to cause the die to be released from the die plate to come into contact with the contact area.

13. The method of claim 12, wherein step (a) includes:
receiving the die plate having a plurality of dies attached to the first surface of the die plate, the die plate having a plurality of holes therein, wherein each die of the plurality of dies covers a corresponding hole in the die plate.

14. The method of claim 12, wherein step (d) includes:
selectively energizing a coil associated with the pin to move the pin into the hole in the die plate.

15. The method of claim 12, wherein step (d) includes:
moving an actuator plate having a plurality of actuators across a pin plate holding the pin, wherein a corresponding actuator selectively actuates the pin.

16. A system to transfer integrated circuit dies, comprising:
a die plate holder to mount a die plate, said die plate having a first surface having a die attached thereto, wherein the die covers a corresponding hole in the die plate;
a pin plate holder to align a pin of a pin plate with the hole in the die plate;
a substrate supply to present a substrate; and
an actuator to selectively actuate the pin to cause the die to be released from the die plate to come into contact with a contact area on a first surface of the substrate.

17. The system of claim 16, wherein said die plate has a plurality of dies attached to the first surface of the die plate, the die plate having a plurality of holes therein, wherein each die of the plurality of dies covers a corresponding hole in the die plate.

18. The system of claim 16, wherein the actuator includes a coil.

19. The system of claim 16, wherein the pin plate holder moves the pin plate across the die plate to selectively move pins of the pin plate into holes of the die plate.

20. The system of claim 16, wherein the pin plate includes at least a portion of the actuator.
